(19) United States
(12) Patent Application Publication
(10) Pub. No.: US 2025/0231491 A1
(43) Pub. Date: Jul. 17, 2025

(54) PHOTOLITHOGRAPHIC METHOD USING SILICON PHOTORESIST

(71) Applicant: SUNTIFIC MATERIALS (WEIFANG), LTD., Weifang, Shandong (CN)

(72) Inventor: Sam SUN, Columbia, MO (US)

(21) Appl. No.: 18/682,425

(22) PCT Filed: Jun. 30, 2023
(86) PCT No.: PCT/CN2023/105374

§ 371 Date: Feb. 8, 2024

(51) Int. Cl. G03F 7/26; G03F 7/075; G03F 7/09; H01L 21/308

(52) U.S. Cl. CPC G03F 7/265; G03F 7/0757; G03F 7/091; G03F 7/094; H01L 21/308

(57) ABSTRACT

Disclosed herein is a method of forming a pattern, the method including: providing a substrate in which a pattern is to be formed; forming a silicon photoresist layer over the substrate; exposing the silicon photoresist to activating wavelengths of radiation; curing the silicon photoresist; developing the cured silicon photoresist to remove the portion of the photoresist that was exposed to the activating wavelengths of radiation and etching the substrate to form the pattern.

This application is a National Phase entry of International Application No. PCT/CN2023/105374 under § 371, filed Jun. 30, 2023, which is hereby incorporated by reference in its entirety.

### FIELD OF THE DISCLOSURE

This disclosure relates to photolithography for the manufacture of microelectronics.

### BACKGROUND

In photolithography, a photoresist is applied to a substrate comprising a layer in which features such as lines or vias are desired to be formed. The photoresist is exposed to activating wavelengths of radiation in an image-wise pattern, cured, and developed to remove uncured portions leaving an image of the cured portions. The developing can be done by application of a developing solution to remove uncured portions. Commonly used photoresists include hydrocarbon-based polymeric materials. The hydrocarbon photoresist is normally applied (by spinning) on bare substrate, a thin organic bottom antireflective coating (BARC), or a thick organic BARC in conjunction with a thin silicon BARC (sometimes called hardmask).

The BARC is desirable to reduce reflection of radiation from the substrate, which can negatively impact the preciseness of the image formed. There remains a need for an improved method forming a pattern for lines or vias.

### SUMMARY

Disclosed herein is a method of forming a pattern, the method comprising: providing a substrate in which a pattern is to be formed; forming a silicon photoresist layer over the substrate; exposing a portion of the silicon photoresist to activating wavelengths of radiation; curing the silicon photoresist; developing the cured silicon photoresist to remove the portion of the photoresist that was exposed to the activating wavelengths of radiation, and etching the substrate to form the pattern.

### BRIEF DESCRIPTION OF THE DRAWINGS

Referring now to the figures, which are exemplary embodiments, and wherein the like elements are numbered alike.

FIGS. 1(a) to 1(c) show a prior art method of forming a pattern using a hydrocarbon photoresist and a hydrocarbon BARC.

FIGS. 2(a) to 2(d) show a prior art method of forming a pattern using a hydrocarbon photoresist and a combination of a silicon-containing BARC and a hydrocarbon-containing BARC.

FIGS. 3(a) to 3c) show an example of a method of forming a pattern using a hydrocarbon-containing BARC and a silicon photoresist.

FIGS. 4(a) to 4(c) show an example of a method of forming a pattern using a silicon BARC and a silicon photoresist.

FIGS. 5(a) to 5(c) show an example of a method of forming a pattern using a thick hydrocarbon BARC and a silicon photoresist.

FIGS. 6(a) to 6(c) show an example of a method of forming a pattern in a silicon substrate using a silicon photoresist.

FIGS. 7(a) to 7(c) show an example of a method of forming a pattern in a silicon substrate using a photosensitive hydrocarbon BARC and a silicon photoresist.

### DETAILED DESCRIPTION

In photolithography, a bottom antireflective coating (BARC) includes a chromophore that has strong absorption of the wavelength of the activating radiation. The BARC can reduce reflection of radiation from the substrate, which can negatively impact the preciseness of the image formed. In addition, the BARC can adjust adhesion of the photoresist to the substrate.

The BARC can be a hydrocarbon-based material (also referred to as a hydrocarbon-containing material or a hydrocarbon BARC). Note that while “hydrocarbon” is often to refer to compounds that have only C and H atoms, as used herein “hydrocarbon-based,” “hydrocarbon-containing,” or “hydrocarbon BARC” can include compounds that have only C and H atoms, or compounds that comprise C and H atoms as well as heteroatoms, such as O, N, S, and the like, or a combination thereof.

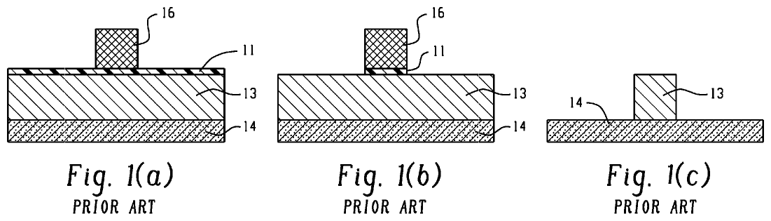

The hydrocarbon-containing BARC comprises a hydrocarbon-containing polymer, which can be cured to ensure the hydrocarbon BARC is resistant to the developing solution for the photoresist. This cure can occur, for example, at around 200° C. Due to the high cure temperature, the chromophore is preferably grafted onto the polymer chain to avoid migration (e.g., outgassing) during the high temperature cure. For example, as shown in FIG. 1(a), a thin, cured hydrocarbon BARC 11 is formed on a substrate comprising a polysilicon layer 13 on a silicon oxide 14. A hydrocarbon photoresist layer is applied over the hydrocarbon BARC 11, exposed to activating wavelengths of radiation, and developed to form a patterned hydrocarbon photoresist 16.

After development of the photoresist, the BARC that is exposed is at least partially removed by reactive ion etching, referred to herein as “RIE,” and the substrate can also patterned by etching, e.g., RIE. As shown in in FIG. 1(b), the hydrocarbon BARC 11 is etched using RIE to expose the polysilicon layer 13. Next, as shown in In FIG. 1(c), RIE is used to etch the polysilicon layer 13 to form a pattern protected by the hydrocarbon photoresist 16, and the remaining photoresist 16 and hydrocarbon BARC 11 removed. Residual photoresist can also be removed using a stripper solution.

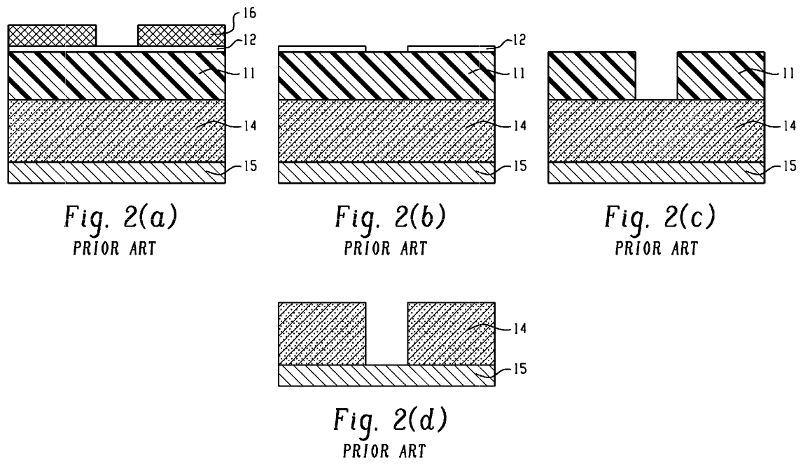

Lack of etch selectivity between a hydrocarbon photoresist and a hydrocarbon BARC limits effective use of hydrocarbon photoresists with thick hydrocarbon BARC layers. Thus if a thick hydrocarbon BARC is used, an additional thin silicon BARC (also referred to as a hardmask) is also typically used. For example, as shown in FIG. 2(a), a hydrocarbon photoresist is applied, exposed, and developed to form a pattern of hydrocarbon photoresist 16 on a stack comprising, in order from the bottom, a metal 15, silicon oxide 14, a thick hydrocarbon BARC 11, and a thin silicon BARC 12. In FIG. 2(b), the silicon BARC 12 is etched and the hydrocarbon photoresist removed by RIE. In FIG. 2(c), the hydrocarbon BARC 11 is etched using the silicon BARC as a mask and the silicon BARC is removed. In FIG. 2(d), a pattern is etched in the silicon oxide 14 using the hydrocarbon BARC 11 as a mask and the hydrocarbon BARC 11 is removed.

Because of inadequate etch resistance, hydrocarbon photoresists cannot be effectively used with silicon-containing BARCs alone. Also, although silicon containing hard masks have been disclosed, see e.g., U.S. Pat. Nos. 8,911,932; 8,728,710; CN102236253; and JP6144000, improved methods are desired to simplify and/or enhance the photolithography processes.

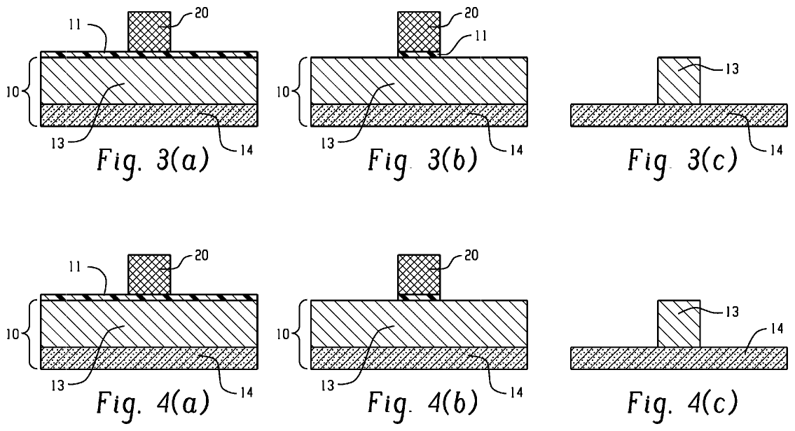

To address these and other deficiencies, the method disclosed herein comprises providing a substrate that includes a portion on which a pattern is desired to be formed. A silicon photoresist is applied over the substrate, exposed to an activating wavelength of radiation in an image-wise pattern, cured, and developed to remove the exposed portion of the silicon photoresist. The activating wavelength of radiation can be a wavelength in the range of, for example, 10 to 400 nanometers (nm), e.g., 13.5, 193, 248, or 365 nm. The developing step can directly expose a portion of the substrate. (See e.g., FIG. 6). Alternatively, a BARC can be formed on the substrate before application of the silicon photoresist, in which case the development of the photoresist exposes the BARC, which in turn is etched (e.g., using reactive ion etching, RIE) to expose a portion of the substrate. (See, e.g., FIGS. 3-5 and 7). Once the substrate is exposed, the pattern can be etched (e.g., using RIE) into the substrate using the silicon photoresist and/or the intervening BARC as a mask.

The substrate can comprise a metal, a semiconductor, a dielectric material, or a combination or two or more thereof. For example, the substrate can include a semiconducting material, such as Si, SiGe, SiGeC, SiC, GaAs, InAs, InP, or other Group III/V or Group II/VI compound semiconductors. The substrate can include, for example, a silicon wafer or process wafer such as that produced in various steps of a semiconductor manufacturing process, such as an integrated semiconductor wafer. The substrate can include multiple layers or can be a single layer. The substrate can include a layered substrate such as, for example, Si/SiGe, Si/SiC, silicon-on-insulator (SOI), or a silicon germanium-on-insulator (SGOI). The substrate can comprise silicon, polysilicon, silicon dioxide or an aluminum-aluminum oxide microelectronic wafer, gallium arsenide, silicon carbide, ceramic, quartz, metal, or a combination of two or more thereof. For example, the substrate can comprise a layer of polysilicon over a layer of silicon oxide. As another example, the substrate can comprise silicon oxide over a layer of metal. As yet another example, the substrate can comprise, consist essentially of, or consist of a silicon substrate. When a substantially bare silicon substrate is used, a surface of the silicon substrate can be treated prior to application of the silicon photoresist. For example, the silicon substrate can be treated with an adhesion promoter, such as, for example a silylating agent, (e.g., alkyl silyl amine such as bis(trimethylsilyl)amine also referred to as hexamethyldisilazane or HMIDS).

The silicon photoresist composition can comprise a silicon-containing resin, a catalyst capable of catalyzing condensation reaction of the silicon-containing resin, and a photoacid generator, wherein the catalyst can be deactivated by the presence of acid such that it loses the capability of catalyzing the condensation reaction. This catalyst can be referred to as a condensation catalyst, or cure catalyst. Thus, when a region of a coating comprising the silicon photoresist composition is exposed to activating radiation, an acid is formed and the catalyst is deactivated. Subsequent cure takes place in the unexposed regions. Development in a suitable developing solution removes the exposed regions. Thus, the silicon photoresist can be a positive tone photoresist.

The silicon-containing polymeric resin can be prepared from one or more monomers with molecular structures of

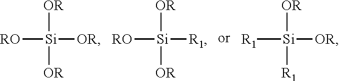

or a combination of two or more thereof. Each R is independently in each occurrence hydrogen or an alkyl group of 1 to 4 carbon atoms, preferably 1 to 3 carbon atoms, and more preferably 1 or 2 carbon atoms, R is preferably an alkyl group of 1 or 2 carbon atoms. Each R₁ is independently at each occurrence a monovalent organic group having 1 to 30 carbon atoms, and optionally including 1 to 5 heteroatoms selected from N, O, P, S, or a combination of two or more thereof. A combination comprising at least one of the foregoing may be used. For example, each R₁ can be an alkyl group having 1 to 30 carbon atoms, an aryl group having 6 to 30 carbon atoms, an alkene group having 2 to 30 carbon atoms, or an alicyclic group having 3 to 30 carbon atoms, each of which optionally includes —O—, —CO—, —OCO—, —COO—, or —OCOO— as part of its structure. Each R₁ can independently be further substituted by one or more epoxy groups. R₁ is preferably an alkyl group of 1 or 2 carbon atoms to provide a cured resin with silicon content above 42 weight percent, based on a total weight of the cured resin.

Examples of preferred monomers include of methyltrimethoxy silane, tetraethoxysilane, tetramethoxysilane, tetraethoxysilane, methyltrimethoxysilane, methyltriethoxysilane, ethyltrimethoxysilane, ethyltriethoxysilane, vinyltrimethoxysilane, vinyltriethoxysilane, propyltrimethoxysilane, propyltriethoxysilane, isopropyltrimethoxysilane, isopropyltriethoxysilane, butyltrimethoxysilane, butyltriethoxysilane, isobutyltrimethoxysilane, isobutyltriethoxysilane, allyltrimethoxysilane, allyltriethoxysilane, cyclopentyltrimethoxysilane, cyclopentyltriethoxysilane, cyclohexyltrimethoxysilane, cyclohexyltriethoxysilane, cyclohexenyltrimethoxysilane, cyclohexenyltriethoxysilane, phenyltrimethoxysilane, phenyltriethoxysilane, benzyltrimethoxysilane, benzyltriethoxysilane, phenethyltrimethoxysilane, phenethyltriethoxysilane, dimethyldimethoxysilane, dimethyldiethoxysilane, diethyldimethoxysilane, diethyldiethoxysilane, methylethyldimethoxysilane, methylethyldiethoxysilane, dipropyldimethoxysilane, dibutyldimethoxysilane, methylphenyldimethoxysilane, methylphenyldiethoxysilane, trimethylmethoxysilane, dimethylethylmethoxysilane, dimethylphenylmethoxysilane, dimethylbenzylmethoxysilane, dimethylphenethylmethoxysilane, or the like, or a combination or two or more thereof. A combination comprising at least one of the foregoing may be used.

The polymerization of the monomers can occur in an organic solvent. Exemplary organic solvents for use in the polymerization include methanol, ethanol, 1-propanol, 2-propanol, 1-butanol, 2-butanol, 2-methyl-1-propanol, acetone, acetonitrile, tetrahydrofuran, toluene, hexane, ethyl acetate, methyl ethyl ketone, methyl isobutyl ketone, cyclohexanone, methyl amyl ketone, butanediol monomethyl ether, propylene glycol monomethyl ether, ethylene glycol monomethyl ether, butanediol monoethyl ether, propylene glycol monoethyl ether, ethylene glycol monoethyl ether, propylene glycol dimethyl ether, diethylene glycol dimethyl ether, propylene glycol monomethyl ether acetate, propylene glycol monoethyl ether acetate, ethyl pyruvate, butyl acetate, methyl 3-methoxypropionate, ethyl 3-ethoxypropionate, tert-butyl acetate, t-butyl propionate, propylene glycol mono-t-butyl ether acetate, y-butyrolactone, or the like, or a combination of two or more thereof. A combination comprising at least one of the foregoing may be used. The organic solvent can be propylene glycol methyl ether or propylene glycol methyl ether acetate.

The polymerization of the monomers can occur in the presence of one or more polymerization catalysts. The polymerization catalyst can be an acid catalyst. Exemplary acid catalysts include organic acids such as formic acid, acetic acid, oxalic acid, maleic acid, methanesulfonic acid, benzenesulfonic acid, toluenesulfonic acid, or the like, or a combination of two or more thereof, or inorganic acids such as hydrofluoric acid, hydrochloric acid, hydrobromic acid, sulfuric acid, nitric acid, perchloric acid, phosphoric acid, or the like, or a combination of two or more thereof. A combination comprising at least one of the foregoing may be used. The acid catalyst can be acetic acid. The acid catalyst can be used in any suitable amount, such as from 1 to 10 weight percent (wt %), 2 to 8 wt %, or 3 to 7 wt %, based on a total charged weight in a reactor.

The polymerization can occur at temperatures of from 0° C. to 110° C., 20° C. to 110° C., 50° C. to 110° C., or 80° C. to 110° C.

Volatile alkanols formed during the reaction can be removed by distillation as the reaction proceeds. The distillate can also include the catalyst, water, and/or solvent. A nitrogen stream flushed through the reactor can assist distillation. The removal of volatile alkanols can occur during or after the polymerization reaction.

The silicon-containing polymeric resin so formed can comprise a polysiloxane, a polysilsesquioxane, or a combination thereof. For example, the silicon-containing polymeric resin comprise both the polysiloxane and the polysilsesquioxane. The silicon containing polymeric resin can comprise a cross-linked or network structures. The network can include a complex and diverse set of molecular structures of the polysiloxane and the polysilsesquioxane. For example, the network structure can include a variety of structures including the following molecular structure:

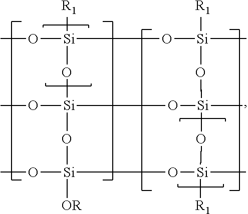

wherein each R and R₁ are each independently as defined herein. However, the above structure is not an exact and complete description of the silicon-containing polymeric resin, such that the selected monomer and polymerization process may provide the most accurate description of the polymer.

The weight average molecular weight (M_{w}) of the silicon-containing polymeric resin before cure can be from 1,000 to 50,000 grams per mole (g/mol), from 1,500 to 30,000 g/mol, from 2,000 to 20,000 g/mol, or from 3,000 to 10,000 g/mol. The M_{W} can be determined using Gel Permeation Chromatography (GPC) with polystyrene standards, as described in Williams and Ward, J. Polymer. Sci., Polymer. Letters, 6, 621 (1968), the content of which is incorporated herein by reference in its entirety.

Exemplary silicon-containing resins can include a siloxane, silsesquioxane, polysiloxane, or polysilsesquioxane, such as methylsiloxane, methylsilsesquioxane, phenylsiloxane, phenylsilsesquioxane, methylphenylsiloxane, methylphenylsilsesquioxane, dimethylsiloxane, diphenylsiloxane, methylphenylsiloxane, polyphenylsilsesquioxane, polyphenylsiloxane, polymethylphenylsiloxane, polymethylphenylsilsesquioxane, substituted, polymethylsilsesquioxane, or a combination of two or more thereof. A combination comprising at least one of the foregoing may be used. These resins can be substituted or unsubstituted.

The silicon-containing resin can be included in the photoresist precursor composition in an amount of 0.5 to 40 wt %, 1 to 30 wt %, or 2 to 20 wt %, based on a total weight of the dielectric precursor composition, corresponding to 10 nanometer to 2 micrometer film thickness at normal spin coating speed (e.g., 500 to 2000 revolutions per minute (RPM)).

The catalyst in the silicon photoresist composition (the cure catalyst or condensation catalyst) can comprise a quaternary ammonium and/or an amine, such as, for example, methylamine, ethylamine, propylamine, butylamine, ethylenediamine, hexamethylenediamine, dimethylamine, diethylamine, ethylmethylamine, trimethylamine, triethylamine, tripropylamine, tributylamine, cyclohexylamine, dicyclohexylamine, monoethanolamine, diethanolamine, dimethyl monoethanolamine, monomethyl diethanolamine, triethanolamine, hexamethylenetetramine, aniline, N,N-dimethylaniline, N,N-dimethylaminopyridine, pyrrole, piperazine, pyrrolidine, piperidine, benzyltriethylammonium chloride (BTEAC), tetramethylammonium chloride (TMAC), guanidine carbonate, tetramethylammonium hydroxide (TMAH), tetramethylammonium acetate (TMAA), tetrabutylammonium hydroxide (TBAH), tetrabutylammonium acetate (TBAA), cetyltrimethylammonium acetate (CTAA), tetramethylammonium nitrate (TMAN), or a combination of two or more thereof. A combination comprising at least one of the foregoing may be used.

The amount of the cure catalyst can be 0.0005 to 0.2 wt %, or 0.001 to 0.05 wt %, based on a total weight of the dielectric precursor composition. The amount of the catalyst can be 0.045 to 4 wt %, or 0.01 to 0.5 wt %, based on the total weight of the silicon-containing polymeric resin.

The photoacid generator is preferably a compound which generates an organic acid by irradiation with actinic ray or radiation. A sensitive wavelength of the photoacid generator is preferably, for example, a wavelength of 10 to 450 nanometers (nm), or 300 to 450 nm. In other words, the photoacid generator is preferably a compound which generates an acid in response to actinic radiation in the above-described wavelength range. In addition, a pKa of the acid generated from the photoacid generator is preferably 4.0 or less and more preferably 3.0 or less.

The photoacid generator can comprise an onium salt, a triazine compound (preferably a halomethylated triazine compound, or more preferably a trichloromethyl-s-triazine compound), an oxime sulfonate compound, a bissulfonyldiazomethane compound, an imide sulfonate compound, a diazodisulfone compound, a disulfone compound, or a nitrobenzylsulfonate compound (preferably an o-nitrobenzylsulfonate compound). Preferably, the photoacid generator includes a sulfonium or iodinium salt, more preferably a compound having a sulfonium cation, or a sulfonate or methides or iodonium cation or sulfonate. Exemplary sulfonium cations include triphenylsulfonium and tris(4-tert-butoxyphenyl)sulfonium. Exemplary sulfonates include trifluoromethanesulfonate and perfluoro-1-butanesulfonate. An exemplary methide includes tris(trifluoromethyl)methide. Exemplary iodonium cations include aryliodonium cations, including diphenyliodonium and bis(4-tert-butylphenyl)iodonium. Exemplary sulfonates include trifluoromethanesulfonate and perfluoro-1-butanesulfonate. A combination comprising at least one of the foregoing may be used.

Exemplary photoacid generators include onium salts such as triphenylsulfonium trifluoromethanesulfonate, triphenylsulfonium trifluoroacetate, 4-methoxyphenyldiphenylsulfonium trifluoromethanesulfonate, 4-methoxyphenyldiphenylsulfonium trifluoroacetate, 4-phenylthiophenyldiphenylsulfonium trifluoromethanesulfonate, 4-phenylthiophenyldiphenylsulfonium, trifluoroacetate·diphenyliodonium trifluoromethane-sulfonate, (p-tert-butoxyphenyl)phenyliodonium trifluoromethanesulfonate, diphenyliodonium p-toluenesulfonate, (p-tert-butoxyphenyl)phenyliodonium p-toluenesulfonate, triphenylsulfonium trifluoromethanesulfonate, (p-tert-butoxyphenyl)diphenylsulfonium trifluoromethane-sulfonate, bis(p-tert-butoxyphenyl)phenylsulfonium trifluoromethane-sulfonate, tris(p-tert-butoxyphenyl)sulfonium trifluoromethanesulfonate, triphenylsulfonium p-toluenesulfonate, (p-tert-butoxyphenyl)diphenylsulfonium p-toluenesulfonate, bis(p-tert-butoxyphenyl)phenylsulfonium p-toluenesulfonate, tris(p-tert-butoxyphenyl)sulfonium p-toluenesulfonate, triphenylsulfonium nonafluorobutane sulfonate, triphenylsulfonium butanesulfonate, trimethylsulfonium trifluoromethanesulfonate, trimethylsulfonium p-toluenesulfonate, cyclohexylmethyl(2-oxocyclohexyl)sulfonium trifluoromethane-sulfonate, cyclohexylmethyl(2-oxocyclohexyl)sulfonium p-toluenesulfonate, dimethylphenylsulfonium trifluoromethanesulfonate, dimethylphenylsulfonium p-toluenesulfonate, dicyclohexylphenylsulfonium trifluoromethanesulfonate, dicyclohexylphenylsulfonium p-toluenesulfonate, trinaphthylsulfonium trifluoromethanesulfonate, cyclohexylmethyl(2-oxocyclohexyl)sulfonium trifluoromethane-sulfonate, (2-norbornyl)methyl(2-oxocyclohexyl)sulfonium trifluoro-methanesulfonate, ethylenebis[methyl(2-oxocyclopentyl)sulfonium trifluoro-methanesulfonate], 1,2′-naphthylcarbonylmethyltetrahydrothiophenium triflate, diphenyliodonium trifluoroacetate, diphenyliodonium trifluoromethanesulfonate, 4-methoxyphenylphenyliodonium trifluoromethanesulfonate, 4-methoxyphenylphenyliodonium trifluoroacetate, phenyl-4-(2′-hydroxy-1′-tetradecaoxy)phenyliodonium trifluoromethanesulfonate, 4-(2′-hydroxy-1′-tetradecaoxy)phenyliodonium hexafluoroantimonate, phenyl-4-(2′-hydroxy-1′-tetradecaoxy)phenyliodonium p-toluenesulfonate, or the like, or a combination of two or more thereof. A combination comprising at least one of the foregoing may be used.

Exemplary diazomethane compounds include bis(benzenesulfonyl)diazomethane, bis(p-toluenesulfonyl)diazomethane, bis(xylenesulfonyl)diazomethane, bis(cyclohexylsulfonyl)diazomethane, bis(cyclopentylsulfonyl)diazomethane, bis(n-butylsulfonyl)diazomethane, bis(isobutylsulfonyl)diazomethane, bis(isoamylsulfonyl)diazomethane, 1-tert-amylsulfonyl-1-(tert-butylsulfonyl)diazomethane, or the like, or a combination of two or more thereof. A combination comprising at least one of the foregoing may be used.

Exemplary triazine compounds include 2-(3-chlorophenyl)-bis(4,6-trichloromethyl)-s-triazine, 2-(4-methoxyphenyl)-bis(4,6-trichloromethyl)-s-triazine, 2-(4-methylthiophenyl)-bis (4,6-trichloromethyl)-s-triazine, 2-(4-methoxy-β-styryl)-bis(4,6-trichloromethyl)-s-triazine, 2-piperonyl-bis (4,6-trichloromethyl)-s-triazine, 2-[2-(furan-2-yl)ethenyl]-bis (4,6-trichloromethyl)-s-triazine, 2-[2-(5-methyl)furan-2-yl)ethenyl]-his (4,6-trichloromethyl)-s-triazine, 2-[2-(4-diethylamino-2-methylphenyl)ethenyl]-bis(4,6-trichloromethyl)-s-triazine, 2-(4-methoxynaphthyl)-bis(4,6-trichloromethyl)-s-triazine, or the like, or a combination of two or more thereof. A combination comprising at least one of the foregoing may be used.

Exemplary imide sulfonate compounds include trifluoromethylsulfonyloxybicyclo[2.2.1]-hept-5-en-dicarboxyimide, succinimide trifluoromethylsulfonate, phthalimidetrifluoromethylsulfonate, N-hydroxynaphthalimidemethanesulfonate, N-hydroxy-5-norbornene-2,3-dicarboxyimide propanesulfonate, or the like, or a combination of two or more thereof. A combination comprising at least one of the foregoing may be used.

A specific example of the photoacid generator is 2-(4-methoxyphenyl)([((4-methylphenyl)sulphonyl)oxy]imino)acetonitrile.

The content of the photoacid generator is preferably 0.01 to 3 wt %, 0.05 to 2 wt %, 0.1 to 1 wt %, or 0.2 wt %, based on the total solid content of the composition.

The mole ratio of the photoacid generator to the catalyst can be, for example, 0.5:1 to 10:1, or 0.5:1 to 5:1, or 0.5:1 to 1.5:1.

The silicon photoresist can have a high silicon atom content—e.g., a silicon content of greater than 35, greater than 38, greater than 39, greater than 40, greater than 41, or at least 42 wt %, and up to 46 or up to 45 wt % atomic silicon, based on total weight of the photoresist composition.

The silicon photoresist can provide better protection against ion bombardment than can a hydrocarbon photoresist. This feature can be beneficial particularly in applications where the photoresist is applied to a bare (treated or untreated) silicon substrate.

Forming the layer of the silicon photoresist on the substrate can include applying a coating composition comprising the silicon-containing resin, the catalyst, the photoacid generator, optionally an additive, and a coating solvent to the substrate.

Exemplary coating solvents also include solvents that are not part of the hydrocarbon solvent family of compounds, such as ketones, including acetone, diethyl ketone, methyl ethyl ketone, or the like, alcohols, esters, ethers, or amines. Examples of solvents include propylene glycol methyl ether (PGME), propylene glycol methyl ether acetate (PGMEA), propylene glycol propyl ether (PGPE), and ethyl lactate (EL).

The coating solvent can be included in the dielectric precursor composition in an amount of 50 to 99 wt %, 55 to 95 wt %, 60 wt to 90 wt %, or 65 to 85 wt %, based on the total weight of the composition.

Suitable methods of applying can include spin coating, spray coating, and the like. The solvent is removed to form a solid layer of the photopatternable dielectric precursor composition.

Optional additional components of the coating composition can include a film modifier to control diffusion of ingredients in the film, or the like, or a combination of two or more thereof.

The film modifiers can be a polymer, oligomer, or a non-polymeric compound. The weight-average molecular weight (M_{w}) of the polymer or oligomer used as the film modifiers is preferably less than 5,000 g/mol, and more preferably less than 2,000 g/mol, as determined by GPC. Molecules of film modifiers have to be small enough to fill in film pores. The film modifier can be compound containing only C and H, a hydrocarbon compound, and is preferably a silicon-containing compound. At least one hydroxyl group is attached to each molecule of the film modifier. The hydroxyl group can participate in the condensation reaction of the film resin. Exemplary hydrocarbon film-modifiers include polyols such as polyetherdiol, glycerol, 2-(hydroxymethyl)-1,3-propanediol, 1,3-dihydroxypropan-2-yl dihydrogen phosphate, ethylene glycol, 1,3-propylene glycol, 1,4-butanediol, 1,5-pentanediol, 1,6-hexanediol, 1,7-heptanediol, 1,8-octanediol, 1,9-nonanediol, 1,10-decanediol, or the like, or a combination two or more thereof. Examples of the branched alkylenediol can include neopentylglycol, 2,4-diethyl-1,5-pentanediol, 2,4-dibutyl-1,5-pentanediol, 3-methyl-1,5-pentanediol, 1-methylethylene glycol, 1-ethylethylene glycol, diethylene glycol, triethylene glycol, tetraethylene glycol, dipropylene glycol, tripropylene glycol, 1,1,1-tris(hydroxymethyl)ethane, 2-hydroxymethyl-1,3-propanediol, 2-ethyl-2-(hydroxymethyl)-1,3-propanediol, 2-hydroxymethyl-2-propyl-1,3-propanediol, 2-hydroxymethyl-1,4-butanediol, 2-hydroxyethyl-2-methyl-1,4-butanediol, 2-hydroxymethyl-2-propyl-1,4-butanediol, 2-ethyl-2-hydroxyethyl-1,4-butanediol, 1,2,3-butanetriol, 1,2,4-butanetriol, 3-(hydroxymethyl)-3-methyl-1,4-pentanediol, 1,2,5-pentanetriol, 1,3,5-pentanetriol, 1,2,3-trihydroxyhexane, 1,2,6-trihydroxyhexane, 2,5-dimethyl-1,2,6-hexanetriol, tris(hydroxymethyl)nitromethane, 2-methyl-2-nitro-1,3-propanediol, 2-bromo-2-nitro-1,3-propanediol, 1,2,4-cyclopentanetriol, 1,2,3-cyclopentanetriol, 1,3,5-cyclohexanetriol, 1,3,5-cyclohexanetrimethanol, butane-1,2,3,4-tetrol(butane-1,2,3,4-tetrol), 2,2-bis(hydroxymethyl)-1,3-propanediol, pentane-1,2,4,5-tetrol, or the like, or a combination of two or more thereof. The film modifier can be 1,1,1-tris(hydroxymethyl)ethane, pentaerythritol, or a combination thereof. Exemplary silicon-containing film modifiers include silanols, such as diphenylsilanediol, diisobutylsilanediol, 1,4-bis(hydroxyldimethylsilyl)benzene, 4-vinylphenylsilanediol, or the like, or a combination of two or more thereof. The content of the film-modifier should not exceed 30 wt %, and more preferably not exceed 10 wt %, and may be 0.01 to 15 wt %, or 0.1 to 10 wt %, of the resin by total weight. Concentrations of film-modifier in compositions are used to control diffusion length of catalysts, photoacid generators, and quenchers. Multiple film-modifiers can be used.

Removal of the solvent can include baking (e.g., on a hotplate surface) at 40 to 120° C., 50 to less than 100° C., or 60 to less than 80° C. for 15 to 120 seconds or 30 to 60 seconds. This baking step must not be long enough or hot enough to cause cure of the silicon-containing resin so that the dried film remains soluble in the developer solution.

Exposing can comprise exposure to an activating wavelength of radiation. To generate a pattern in the silicon photoresist, the exposure is conducted in an image-wise manner. This can occur through a mask or by direct address with a laser. The wavelengths can be, for example, in the range of 10 to 400 nm, or a specific wavelength such as 365 nm, 248 nm, 193 nm, or 13.5 nm.

The exposure deactivates the catalyst. During subsequent heating to cause cure, the silicon-containing resin precursor, therefore, cures (e.g., cross-links) only in the regions not exposed to the radiation. The cure can occur at temperatures of 60 to 120° C., or 80 to 111° C., for 30 to 120 seconds.

The silicon photoresist can be developed with a solution, such as an organic solvent, particularly a polar organic solvent, or an alkaline aqueous solution. Examples of the organic solvent include, but are not limited to, cyclohexanone, propylene glycol methyl ether, methyl acetate, butyl acetate, ethyl acetate, isopropyl acetate, amyl acetate, isoamyl acetate, ethyl methoxyacetate, ethyl ethoxyacetate, propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, propyl-3-methoxypropionate, or the like, or a combination of two or more thereof. A combination comprising at least one of the foregoing may be used. The organic solvents can be propylene glycol methyl ether (PGME), propylene glycol methyl ether acetate (PGMEA), ethyl lactate (EL), or cyclohexanone. Examples of alkaline (basic) developers can be water solutions of organic or inorganic bases, including, for example, tetramethylammonium hydroxide (TMAH), tetraethylammonium hydroxide, ethanolamine, propylamine, ethylenediamine, choline, potassium hydroxide, sodium hydroxide, or a combination thereof. A specific example of a developer is an aqueous solution of tetramethylammonium hydroxide with a concentration of 2.5 to 25 grams per liter (g/L). The development is performed under appropriately determined conditions; i.e., at a temperature of 5 to 50° C., and for a time of 10 to 600 seconds.

Due to high etch resistance, the silicon photoresist can be thinner than the typical thickness for a hydrocarbon photoresist. This is beneficial as a thinner photoresist can provide a more precise pattern. The thickness of the photoresist, when used with a thin BARC, should be thick enough to protect the substrate. The thickness of the photoresist can be from 2, from 5, or from 10 up to 1000 nm, up to 900, up to 800, up to 700, up to 600, up to 500, up to 400, up to 300, up to 200, or up to 100 nm. When used with a thin BARC layer (e.g., thickness of about 2 to 200 nm), the thickness of silicon photoresist can be from 5 nm or from 10 up to 1000 nm, up to 900, up to 800, up to 700, up to 600, up to 500, up to 400, up to 300, or up to 200 nm. Any suitable combination of the foregoing thicknesses may be used. When the silicon photoresist is used with a thick hydrocarbon BARC (e.g., having a thicknesses of 10 to 2000 nm), the silicon photoresist can be thinner, in the range of from 2 nm, from 5 nm, or from 10 up to 200, up to 100, up to 90, up to 80, up to 70, or up to 60 nm.

A hydrocarbon BARC, if used, can comprise a polymer and includes a light absorbing group, e.g., a chromophore. The chromophore can be bonded to the polymer backbone. The polymer can be for example an epoxy cresol novolac, a phenol novolac, an acrylic polymer, a polyester, a polysaccharides, a polyether, polyacetate, a styrenic polymer (e.g., polystyrene or a copolymer of a styrene with another monomer such as acrylonitrile), or a polyimide. The composition for forming hydrocarbon BARC layer can include a cross-linking agent, such as, for example, an aminoplast (e.g., POWDERLINK® 1174, Cymel® products), epoxy, polyol, anhydride, glycidyl ether, vinyl ether, or a combination thereof. The polymer can include an epoxide ring in a repeating unit. For example, the epoxide group account for about 20 to 80 wt %, and preferably about 20 to 40 wt %, of the total weight of the polymer. The chromophore comprises an aromatic or a heterocyclic light absorbing moiety. The chromophore can be covalently bonded to the polymer. For example, the chromophore can have the formula

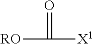

where R is selected from the group consisting of —H and substituted and unsubstituted alkyl groups (preferably C₁-C₈, and more preferably C₁-C₄) and X¹ is an aromatic or heterocyclic light-absorbing moiety. This includes chromophores having phenolic —OH, —COH, and —NH₂ functional groups. The chromophore can comprise, for example, phenyl, a thiophene, a naphthoic acid, anthracene, naphthalene, benzene, chalcone, a phthalimide, pamoic acid, acridine, azo compounds, dibenzofuran, or a derivative thereof.

The hydrocarbon BARC can be uncrosslinked.

The hydrocarbon BARC can be coated, e.g., by spin coating, from a composition comprising the hydrocarbon BARC in a solvent. The solvent can be removed by baking (e.g., at a temperature of 30 to 150° C. or 50 to less than 100° C., for from 10 seconds, or from 30 up to 120 seconds, or up to 90 seconds).

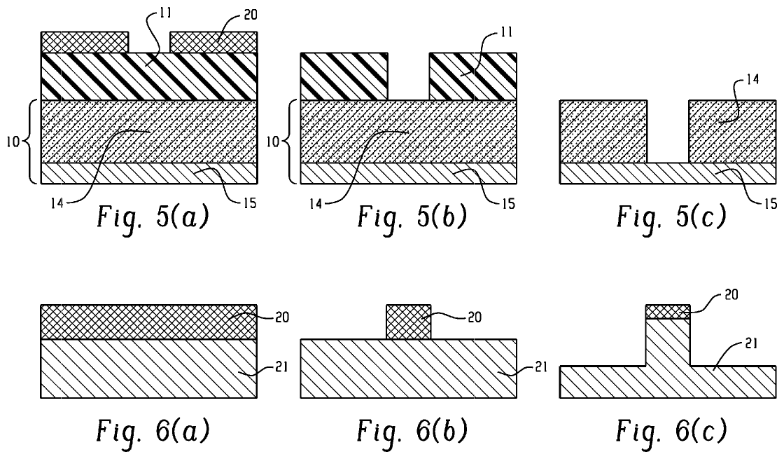

The hydrocarbon BARC can be thin (e.g., having thicknesses 2 to 200 nm, preferably 5 to 60 nm) as shown for example in FIG. 3, or can be thick (e.g., having thicknesses of 10 to 2000 nm, preferably 20 to 1000 nm) as shown, for example, in FIG. 5.

A silicon BARC, if used, can comprise a silicon polymer and can include a light absorbing functional group (e.g., a chromophore). For example, a silicon BARC can comprise an oligomeric or polymeric alkylsiloxane, an oligomeric or polymeric alkylsilsesquioxane, an oligomeric or polymeric arylsiloxane, an oligomeric or polymeric arylsilsesquioxane, an oligomeric or polymeric alkenyl siloxane, an oligomeric or polymeric alkenylsilsesquioxane, or a combination thereof. In the forgoing, the alkyl can comprise, for example, 1, 2, 3, 4, 5, 6, 7 or 8 carbon atoms. In the forgoing. the aryl can comprise, for example, from 6 to 16 carbon atoms. The chromophore can comprise, for example, a phenyl, a thiophene, a naphthoic acid, anthracene, naphthalene, benzene, chalcone, a phthalimide, pamoic acid, acridine, azo compounds, or a dibenzofuran, or a derivative thereof.

The silicon BARC can be coated, e.g., by spin coating, from a composition comprising the silicon BARC in a solvent. The solvent can be removed by baking (e.g., at a temperature of 30 to 150° C., or 50 to less than 100° C., for from 10 seconds, or from 30 up to 120 seconds, or up to 90 seconds).

The silicon BARC can have a thickness in the range of 2 to 200 nm, preferably 5 to 60 nm.

Referring to FIG. 3(a) to 3(c), one example of a method as described herein comprises forming a thin (e.g., 2 to 200 nm) hydrocarbon BARC 11 on a substrate comprising a polysilicon layer 13 on a silicon oxide 14. In FIG. 3(a), a silicon photoresist composition has been applied, image-wise exposed to an activating wavelength of radiation, cured, and developed to remove the photoresist composition in an area that had been exposed, leaving a silicon photoresist 20 in a pattern on the hydrocarbon BARC 11. In FIG. 3(b), the hydrocarbon BARC 11 is etched exposing the polysilicon layer 13 using the silicon photoresist 20 as a mask. In FIG. 3(c) the polysilicon layer 13 has been etched using the remaining silicon photoresist 20 and underlying hydrocarbon BARC 11 as a mask.

Referring to FIG. 4(a) to 4(c), another example of a method as described herein comprises forming a thin (e.g., 2-200 nm) silicon BARC 12 on a substrate comprising a polysilicon layer 13 on a silicon oxide 14. In FIG. 4(a), a silicon photoresist composition has been applied, image-wise exposed to an activating wavelength of radiation, cured, and developed to remove the photoresist composition in an area that has been exposed, leaving a silicon photoresist 20 in a pattern on the silicon BARC 12. In FIG. 4(b), the silicon BARC 12 is etched, exposing the polysilicon layer 13 using the silicon photoresist 20 as a mask. In FIG. 4(c) the polysilicon layer 13 has been etched using the remaining silicon photoresist 20 and underlying silicon BARC 12 as a mask.

Referring to FIG. 5(a) to 5(c), another example of a method as described herein comprises forming a thick (e.g., 10 to 2000 nm) hydrocarbon BARC 11 on a substrate comprising a silicon oxide 14 on a metal 15. In FIG. 5(a), a silicon photoresist composition has been applied, image-wise exposed to an activating wavelength of radiation, cured, and developed to remove the photoresist composition in an area that had been exposed, leaving a silicon photoresist 20 in a pattern on the hydrocarbon BARC 11. In FIG. 5(b), the hydrocarbon BARC 11 is etched exposing the silicon oxide 14 using the silicon photoresist 20 as a mask. In FIG. 5(c) the silicon oxide 14 has been etched using the remaining silicon photoresist 20 and underlying hydrocarbon BARC 11 as a mask.

Referring to FIGS. 6(a) to 6(c), another example of a method as described herein comprises applying a layer of silicon photoresist 20 to a silicon substrate 21. After image-wise exposure, cure, and development, a pattern of the silicon photoresist 20 remains on the silicon substrate 21 as a mask as shown in FIG. 6(b). The silicon substrate (21) is then etched using the silicon photoresist 20 as a mask. A residual of the silicon photoresist 20 can remain as shown in FIG. 6(c), or it can be entirely removed during the etch (not shown). Any remaining silicon photoresist can serve as a mask during subsequent ion implantation of exposed portions of the silicon substrate.

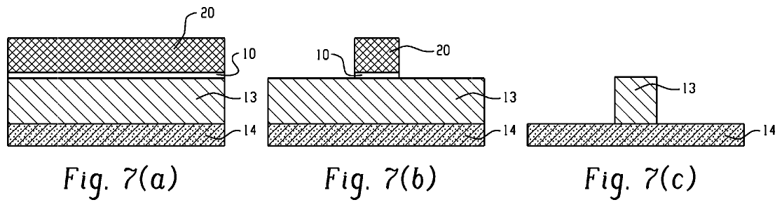

Referring to FIGS. 7(a) to 7(c), another example of a method as described herein comprises forming a thin (e.g., 2 to 200 nm) photosensitive hydrocarbon BARC 10 on a substrate comprising a polysilicon layer 13 on a silicon oxide 14. The photosensitive BARC is positive tone in that the dissolution rate in developer increases when the photosensitive BARC is exposed to the activating radiation.

Such photosensitive hydrocarbon BARC compositions can comprise an aromatic polymer resin and a photoactive agent. For example, the aromatic polymer resin can comprise a novolac resin (a polymer derived from phenols and formaldehydes), a polyamic acid or polyamic acid ester resin, or a combination thereof. For example, the hydrocarbon BARC composition can comprise a novolac resin and diazonaphthoquinone (DNQ). The DNQ inhibits the dissolution of the novolac resin, and upon exposure to light the dissolution rate increases, potentially increasing above the dissolution rate of the base novolac resin. The hydrocarbon BARC composition can comprise a novolac resin, DNQ, and a polyamic acid or polyamic acid ester. The polyamic acid or polyamic acid ester can be present in amounts of 2 to 20 wt %, or 5 to 10 wt %, based on total weight of the hydrocarbon BARC composition. A photosensitive hydrocarbon BARC comprising a novolac resin, and DNQ can be developed in a basic or alkaline developer. Examples of alkaline (basic) developers can be water solutions of organic or inorganic bases, including, for example, tetramethylammonium hydroxide (TMAH), tetraethylammonium hydroxide, ethanolamine, propylamine, ethylenediamine, choline, potassium hydroxide, sodium hydroxide, or a combination thereof. A specific example of the developing solution can comprise a 0.1 to 0.4 Normal (N) tetralkyl ammonium hydroxide, (e.g., a C1 to C4 tetraalkyl ammonium hydroxide such as tetramethylammonium hydroxide).

The polyamic acid or polyamic acid ester can protect against damage to the hydrocarbon BARC from the mixed solvents used for the silicon photoresist. The polyamic acid or polyamic acid ester can be a reaction product of a dianhydride, particularly an aromatic dianhydride, with a diamine, particularly, an aromatic diamine.

Examples of aromatic dianhydrides include pyromellitic dianhydride, biphenyl tetracarboxylic dianhydride, pyromellitic dianhydride benzophenone tetracarboxylic dianhydride, diphenyl ether tetracarboxylic acid dianhydride; hydroquinone diphthalic anhydride; isopropylidenediphenoxy)bis-(phthalic anhydride); (hexafluoroisopropylidene)diphthalic anhydride. or a combination of two or more thereof. In an aspect, a combination comprising at least one of the foregoing may be used. Examples of diamines phenylenediamine, oxydianiline, or a combination thereof.

FIG. 7(a) shows the film stack comprising a silicon photoresist 20 on a photosensitive hydrocarbon BARC 10 on a polysilicon layer 13 on a silicon dioxide layer 14. In FIG. 7(b) the silicon photoresist composition and the photosensitive hydrocarbon BARC have been image-wise exposed to an activating wavelength of radiation, cured, and developed to remove the photoresist composition and the photosensitive hydrocarbon BARC in an area that had been exposed, leaving a silicon photoresist 20 in a pattern on the photosensitive hydrocarbon BARC 10. Note that the exposing can include exposure of a region of the silicon photoresist 20 to radiation which simultaneously exposes the underlying photosensitive hydrocarbon BARC 10 to radiation. The developing can occur sequentially, first developing the silicon photoresist and then developing the underlying photosensitive BARC. Alternatively, the developing of both layers can occur simultaneously using a mixed solution an alkaline developer as described herein. In FIG. 7(c), the polysilicon layer 13 has been etched using the silicon photoresist 20 and underlying photosensitive hydrocarbon BARC 10 as a mask.

Also disclosed herein is an article made by the methods described herein. For example, the article can be an electronic device, such as a chip or integrated circuit or display device or a system comprising such a device. Examples of such systems include computers, cell phones, transportation vehicles, appliances, manufacturing systems, robotic devices, and the like.

### EXAMPLES

### Example 1: Synthesis of Silicon-Containing Polymeric Resin for Silicon Photoresist

In a 500-mL round bottom flask, 65 grams of methyltrimethoxy silane, 30 grams of tetraethoxy silane, 10 grams of phenyltrimethoxy silane, 250 grams of 1-methoxy-2-propanol acetate, 48 grams of water, and 10 grams of acetic acid were combined, mixed well, and distilled for five hours. The flask was removed from the distillation heater and transferred to a rotary evaporator to remove all the solvents over 40 minutes at a temperature of 80° C. under a vacuum of 20 Torr. The silicon-containing resin was recovered from the flask.

### Example 2: Formulating Thin Silicon Photoresist Coating Composition

Five grams of the silicon-containing polymeric resin obtained as set out in Example 1 was combined with 90 grams n-butanol, 10 grams of propylene carbonate, 0.004 grams of benzenyl trimethyl ammonium chloride, and 0.12 grams of mixed triarylsulfonium hexafluoro antimonate salts (TR-PAG-201, Tronly New Electrionic Materials Co., Ltd, Changzhou, China) in a container, and mixed until all ingredients were dissolved. This solution is the liquid form of thin silicon photoresist.

### Example 3: Formulating Thick Silicon Photoresist Coating Composition

Twenty grams of silicon-containing polymeric resin obtained as discussed in Example 1, was combined with 30 grams of n-butanol, 10 grams of propylene carbonate, 0.008 grams of benzenyl trimethyl ammonium chloride, and 0.24 grams of mixed triarylsulfonium hexafluoro antimonate salts (TR-PAG-201, Tronly New Electronic Materials Co., Ltd, Changzhou, China) in a container and mixed until all ingredients were dissolved. This solution is the liquid form of thick silicon photoresist.

### Example 4: Formulating a Thin Hydrocarbon BARC Composition

Two grams of polystyrene resin with a weight average molecular weight of 50,000 Daltons were dissolved in 200 grams of 1-methoxy-2-propanol acetate. This solution is the liquid form of a thin hydrocarbon BARC.

### Example 5: Formulating a Thick Hydrocarbon BARC Composition

One hundred eighty grams of acrylonitrile-styrene copolymer resin with a weight average molecular weight of 50,000 Daltons were dissolved in 720 grams of 1-methoxy-2-porpanol acetate. This solution is the liquid form of an acrylonitrile-styrene thick hydrocarbon BARC.

### Example 6: Formulating Another Thick Hydrocarbon BARC Composition

Forty grams of Novolac resin with a weight average molecular weight of 9,000 Daltons, 4 grams of hexmethoxymethylmelamine, and 0.4 grams of p-toluenesulfonic acid were dissolved in 92 grams of 1-methoxy-2-porpanol acetate and 40 grams of 1-methoxy-2-propanol. This solution is the liquid form of a Novolac thick hydrocarbon BARC.

### Example 7: Formulating a Thin Silicon BARC Composition

In a 500-mL round bottom flask, 52 grams of methyltrimethoxy silane, 8 grams of phenyltrimethoxy silane, and 24 grams of β-(3,4-epoxycyclohexane)ethyl trimethoxy silane, 240 grams of 1-methoxy-2-propanol acetate, 40 grams of water and 8 grams of acetic acid were combined, mixed well, and distilled for five hours. A silicon-containing polymeric resin was formed in the flask. Ten grams of this silicon-containing polymeric resin, 0.08 grams of p-toluenesulfonic acid, and 590 grams of n-butanol were combined and mixed until all ingredients were dissolved. This solution is the liquid form of thin silicon BARC.

### Example 8: Process of Thick Silicon Photoresist with a Thin Hydrocarbon BARC

A thin hydrocarbon BARC composition as in Example 4 was spin-coated on a silicon wafer with a spin speed of 2000 revolution per minute and then baked at 120° C. for 60 seconds, resulting a film of 17 nanometers. The thick silicon photoresist composition from Example 3 was then spin coated on the thin hydrocarbon BARC film with a spin speed of 1000 revolution per minute, forming a film of about 800 nanometers. The wafer with these coatings was image-wise exposed to radiation having a wavelength of 365 nm to generate acid in the exposed regions. The wafer was then baked on a hot surface with a temperature of 120° C. for 60 seconds. Following this bake, the wafer was submerged in a 2.38 wt % solution of tetramethyl ammonium hydroxide in water for 20 seconds to form the desired patterns form on the silicon photoresist film.

### Example 9: Process of Thick Silicon Photoresist with a Thin Silicon BARC

A thin silicon BARC composition as in Example 7 was spin-coated on a silicon wafer with a spin speed of 2000 revolution per minute and then baked at 150° C. for 60 seconds, resulting a film of about 20 nanometers. The thick silicon photoresist composition as in Example 3 was then spin coated on the thin hydrocarbon BARC film with a spin speed of 1000 revolution per minute, forming a film having a thickness of 800 nanometers. The wafer with these coatings was image-wise exposed to radiation having a wavelength of 365 nm to generate acid in the exposed regions. The wafer was then baked on a hot surface with a temperature of 120° C. for 60 seconds. Following this bake, the wafer was submerged in a 2.38 wt % solution of tetramethyl ammonium hydroxide in water for 20 seconds to form the desired patterns form on the silicon photoresist film.

### Example 10: Process of Thin Silicon Photoresist with a Thick Hydrocarbon BARC

A thick hydrocarbon BARC composition as in Example 5 was spin-coated on a silicon wafer with a spin speed of 3000 revolution per minute and baked at 150° C. for 60 seconds, resulting a film of about 2000 nanometers. A thin silicon photoresist as in Example 2 was then spin-coated on the thick hydrocarbon BARC film with a spin speed of 2000 revolution per minute, forming a film of about 100 nanometers. The wafer with these coatings was image-wise exposed to radiation having a wavelength of 365 nm to generate acid in the exposed regions. The wafer was then baked on a hot surface with a temperature of 120° C. for 60 seconds. Following this bake, the wafer was submerged in a 2.38 wt % solution of tetramethyl ammonium hydroxide in water for 20 seconds to form the desired patterns form on the silicon photoresist film.

### Example 11: Process of Thin Silicon Photoresist with Another Thick Hydrocarbon BARC

A thick hydrocarbon BARC as in Example 6 was spin-coated on a silicon wafer with a spin speed of 3000 revolution per minute and baked at 150° C. for 60 seconds, resulting a film of about 2000 nanometers. A thin silicon photoresist of Example 2 on the thick hydrocarbon BARC film with a spin speed of 2000 revolution per minute, forming a film of about 100 nanometers. The wafer with these coatings was image-wise exposed to radiation having a wavelength of 365 nm to generate acid in the exposed regions. The wafer was then baked on a hot surface with a temperature of 120° C. for 60 seconds. Following this bake, the wafer was submerged in a 2.38 weight percentage of tetramethyl ammonium hydroxide water solution for 20 second to form the desired patterns form on the silicon photoresist film.

### Example 12: Process of Thick Silicon Photoresist on an HMIDS Treated Silicon Surface

On a HIDS-pretreated silicon wafer surface, the thick silicon photoresist as in Example 3 was spin-coated with a spin speed of 1000 revolution per minute, forming a film of about 800 nanometers. The wafer with these coatings was image-wise exposed to radiation having a wavelength of 365 nm to generate acid in the exposed regions. The wafer was then baked on a hot surface with a temperature of 120° C. for 60 seconds. Following this bake, the wafer was submerged in a 2.38 weight percentage of tetramethyl ammonium hydroxide water solution for 20 second to form the desired patterns form on the silicon photoresist film.

### Example 13: Process of Thick Silicon Photoresist on a Bare Silicon Surface

On a precleaned and pre-dried silicon wafer surface, the thick silicon photoresist as in Example 3 was spin-coated with a spin speed of 1000 revolution per minute, forming a film of about 800 nanometers. The wafer with these coatings was image-wise exposed to radiation having a wavelength of 365 nm to generate acid in the exposed regions. The wafer was then baked on a hot surface with a temperature of 120° C. for 60 seconds. Following this bake, the wafer was submerged in a 2.38 weight percentage of tetramethyl ammonium hydroxide water solution for 20 second to form the desired patterns form on the silicon photoresist film.

This disclosure further encompasses the following aspects.

Aspect 1: A method of forming a pattern, the method comprising: providing a substrate in which a pattern is to be formed; forming a layer of a silicon photoresist over the substrate; exposing a portion of the silicon photoresist to activating wavelengths of radiation; curing the silicon photoresist; developing the cured silicon photoresist to remove the portion of the photoresist that was exposed to the activating wavelengths of radiation, and etching the substrate to form the pattern.

Aspect 2: The method of Aspect 1, wherein the silicon photoresist comprises, before cure, a silicon-containing resin, a catalyst capable of catalyzing condensation reaction of the silicon-containing resin, and a photoacid generator, wherein the catalyst is characterized in that it is deactivated by the presence of acid such that it loses the capability of catalyzing the condensation reaction.

Aspect 3: The method of Aspect 1 or 2 wherein the silicon photoresist comprises at least 35%, preferably at least 40%, more preferably greater than 41% by weight atomic silicon based on total weight of the silicon photoresist.

Aspect 4: The method of any of the previous Aspects wherein the substrate comprises silicon, polysilicon, silicon dioxide or aluminum-aluminum oxide microelectronic wafers, allium arsenide, silicon carbide, ceramic, quartz, metal or combinations of two or more thereof.

Aspect 5. The method of any of the previous Aspects further comprising forming a bottom anti-reflective coating comprising a polymer on the substrate, and wherein the layer of the silicon photoresist is formed on the bottom anti-reflective coating, wherein developing the cured silicon photoresist exposes a portion of the bottom anti-reflective coating, and further comprising etching the exposed portion of the bottom anti-reflective coating to expose a portion of the substrate before etching the substrate.

Aspect 6: The method of Aspect 5 wherein the bottom anti-reflective coating is characterized by one or both of the following: the polymer is un-crosslinked; the bottom anti-reflective coating comprises a chromophore that is not grafted to the polymer.

Aspect 7: The method of Aspect 5 or 6, wherein the bottom anti-reflective coating comprises a hydrocarbon-containing polymer.

Aspect 8: The method of Aspect 5 or 6, wherein the bottom anti-reflective coating comprises a silicon-containing polymer.

Aspect 9: The method of Aspect 8 wherein the bottom anti-reflective coating is derived from an alkyl siloxane, an alkylsilsesquioxane, an arylsiloxane, an arylsilsesquioxane, an alkenyl siloxane, an alkenylsilsesquioxane, or a combination of two or more thereof.

Aspect 10: The method of Aspect 5, 6, or 7 wherein the bottom anti-reflective coating is not crosslinked.

Aspect 11: The method of Aspect 5, 8 or 9 wherein the bottom anti-reflective coating is crosslinked.

Aspect 12: The method of any one of the previous Aspects wherein the silicon photoresist layer has a thickness of 2 to 1000 nm.

Aspect 13: The method of any one of Aspects 5-11 wherein the silicon photoresist layer has a thickness of 2 to 1000 nm and the bottom anti-reflective coating has a thickness of 2 to 200 nm.

Aspect 14: The method of any one of Aspects 5-11 wherein the silicon photoresist layer has a thickness of 2 to 200 nm, preferably 3 to 90, more preferably 5 to 60 nm, and the bottom anti-reflective coating has a thickness of 10 to 2000 nm, preferably 85 to 1000 nm.

Aspect 15: The method of any one of the previous Aspects wherein the substrate comprises a layer in which a pattern is to be formed said layer comprising polysilicon or silicon oxide.

Aspect 16: The method of Aspect 1 wherein the layer in which the substrate consists essentially of silicon or silicon treated with an adhesion promoter.

Aspect 17: The method of Aspect 16, wherein the adhesion promoter is a silylating agent.

Aspect 18: The method of any one of Aspects 1-4 further comprising forming a bottom anti-reflective coating on the substrate, wherein the layer of the silicon photoresist is formed on the bottom anti-reflective coating, and wherein the bottom anti-reflective coating comprises a positive tone photosensitive hydrocarbon-containing composition, wherein the exposing the silicon photoresist to activating wavelengths of radiation simultaneously exposes a portion of the bottom anti-reflective coating to the activating wavelengths of radiation, further comprising developing the exposed bottom anti-reflective coating to remove the exposed portion of the photosensitive bottom anti-reflective coating and expose a portion of the substrate.

Aspect 19: The method of Aspect 18 wherein the photosensitive hydrocarbon-containing composition comprises a novolac resin and diazonaphthoquinone.

Aspect 20: The method of Aspect 18 or 19 wherein the developing of the bottom anti-reflective coating and the developing of the silicon photoresist occurs simultaneously using a basic solution.

Aspect 21: An article made by the method of anyone of Aspects 1-20.

All ranges disclosed herein are inclusive of the endpoints, and the endpoints are independently combinable with each other (e.g., ranges of “up to 25 wt %, or, more specifically, 5 wt % to 20 wt %”, is inclusive of the endpoints and all intermediate values of the ranges of “5 wt % to 25 wt %,” etc.). Moreover, stated upper and lower limits can be combined to form ranges (e.g., “at least 1 or at least 2 weight percent” and “up to 10 or 5 weight percent” can be combined as the ranges “1 to 10 weight percent,” or “1 to 5 weight percent” or “2 to 10 weight percent” or “2 to 5 weight percent”).

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The disclosure can alternately comprise, consist of, or consist essentially of, any appropriate components herein disclosed. The disclosure can additionally, or alternatively, be formulated so as to be devoid, or substantially free, of any components, materials, ingredients, adjuvants or species used in the prior art compositions or that are otherwise not necessary to the achievement of the function and/or objectives of the present disclosure.

All cited patents, patent applications, and other references are incorporated herein by reference in their entirety. However, if a term in the present application contradicts or conflicts with a term in the incorporated reference, the term from the present application takes precedence over the conflicting term from the incorporated reference.

Unless specified to the contrary herein, all test standards are the most recent standard in effect as of the filing date of this application, or, if priority is claimed, the filing date of the earliest priority application in which the test standard appears.

1. A method of forming a pattern, the method comprising:
providing a substrate in which a pattern is to be formed;
forming a layer of a silicon photoresist over the substrate;
exposing a portion of the silicon photoresist to an activating wavelength of radiation;
curing the silicon photoresist;
developing the cured silicon photoresist to remove the portion of the photoresist that was exposed to the activating wavelengths of radiation, and
etching the substrate to form the pattern.

2. The method of claim 1, wherein the silicon photoresist comprises, before cure, a silicon-containing resin, a catalyst capable of catalyzing a condensation reaction of the silicon-containing resin, and a photoacid generator, wherein the catalyst is deactivated by the presence of acid such that it loses the capability of catalyzing the condensation reaction.

3. The method of claim 1, wherein the silicon photoresist comprises at least 35 wt %, preferably at least 40 wt %, or more preferably greater than 41 wt % of atomic silicon, based on a total weight of the silicon photoresist.

4. The method of claim 1, wherein the substrate comprises silicon, polysilicon, silicon dioxide or aluminum-aluminum oxide microelectronic wafers, allium arsenide, silicon carbide, ceramic, quartz, metal or combinations of two or more thereof.

5. The method of claim 1, further comprising forming a bottom anti-reflective coating comprising a polymer on the substrate, and
wherein the layer of the silicon photoresist is formed on the bottom anti-reflective coating, wherein developing the cured silicon photoresist exposes a portion of the bottom anti-reflective coating, and
further comprising etching the exposed portion of the bottom anti-reflective coating to expose a portion of the substrate before etching the substrate.

6. The method of claim 5, wherein the bottom anti-reflective coating comprises at least one:
the polymer is un-crosslinked; and
the bottom anti-reflective coating comprises a chromophore that is not grafted to the polymer.

7. The method of claim 5, wherein the bottom anti-reflective coating comprises a hydrocarbon-containing polymer.

8. The method of claim 5, wherein the bottom anti-reflective coating comprises a silicon-containing polymer.

9. The method of claim 8, wherein the bottom anti-reflective coating is derived from an alkylsiloxane, an alkylsilsesquioxane, an arylsiloxane, an arylsilsesquioxane, an alkenyl siloxane, an alkenylsilsesquioxane, or a combination of two or more thereof.

10. The method of claim 5, wherein the bottom anti-reflective coating is not crosslinked.

11. The method of claim 5, wherein the bottom anti-reflective coating is crosslinked.

12. The method of claim 1, wherein the silicon photoresist layer has a thickness of 2 to 1000 nm.

13. The method of claim 5, wherein the silicon photoresist layer has a thickness of 2 to 1000 nm, and the bottom anti-reflective coating has a thickness of 2 to 200 nm.

14. The method of claim 5, wherein the silicon photoresist layer has a thickness of 2 to 200 nm, preferably 3 to 90, more preferably 5 to 60 nm, and the bottom anti-reflective coating has a thickness of 10 to 2000 nm, preferably 85 to 1000 nm.

15. The method of claim 1, wherein the substrate comprises a layer in which a pattern is to be formed, the layer comprising polysilicon or silicon oxide.

16. The method of claim 1, wherein the layer in which the substrate comprises silicon or silicon treated with an adhesion promoter.

17. The method of claim 16, wherein the adhesion promoter is a silylating agent.

18. The method of claim 1, further comprising
forming a bottom anti-reflective coating on the substrate, wherein the layer of the silicon photoresist is formed on the bottom anti-reflective coating, and wherein the bottom anti-reflective coating comprises a positive tone photosensitive hydrocarbon-containing composition,
wherein the exposing the silicon photoresist to the activating wavelength of radiation simultaneously exposes a portion of the bottom anti-reflective coating to the activating wavelengths of radiation,
further comprising developing the exposed bottom anti-reflective coating to remove the exposed portion of the bottom anti-reflective coating and expose a portion of the substrate.

19. The method of claim 18, wherein the photosensitive hydrocarbon-containing composition comprises a novolac resin and diazonaphthoquinone.

20. (canceled)

21. An article made by the method of claim 1.
